(19) United States
(12) Patent Application Publication
(10) Pub. No.: US 2026/0305226 A1
(43) Pub. Date: Oct. 1, 2026

(54) BONDING APPARATUS, BONDING SYSTEM, AND BONDING METHOD

(71) Applicant: Tokyo Electron Limited, Tokyo (JP)

(72) Inventor: Tetsuya MAKI, Koshi-shi, Kumamoto (JP)

(73) Assignee: Tokyo Electron Limited, Tokyo (JP)

(21) Appl. No.: 19/488,919

(22) PCT Filed: May 20, 2024
(86) PCT No.: PCT/JP2024/018432

§ 371 Date: Dec. 1, 2025

(30) Foreign Application Priority Data
Jun. 2, 2023 (JP) 2023-091856

(51) Int. Cl. H10P 72/00; H10P 72/50; H10P 72/78

(52) U.S. Cl. CPC H10P 72/0428; H10P 72/0404; H10P 72/0606; H10P 72/53; H10P 72/78

(57) ABSTRACT

A bonding apparatus 41 includes a first holder 230, a second holder 231, a movable member 281a and a motor 281c. The first holder 230 is configured to attract and hold a first substrate W 1 from above. The second holder 231 is disposed below the first holder 230, and configured to attract and hold a second substrate W2 from below. The movable member 281a is configured to be linearly movable along a vertical direction, and also configured to press, with a tip end thereof, a central portion of the first substrate W1. The motor 281c is configured to move the movable member 281a along the vertical direction.

### DESCRIPTION

### Technical Field

The various aspects and embodiments described herein pertain generally to a bonding apparatus, a bonding system, and a bonding method.

### Background

Conventionally, there is known a bonding apparatus that bonds substrates such as semiconductor wafers together (see Patent Document 1).

### PRIOR ART DOCUMENT

Patent Document 1: Japanese Patent Laid-open Publication No. 2018-147944

### DISCLOSURE OF THE INVENTION

### Problems to Be Solved By the Invention

Exemplary embodiments provide a technique capable of improving bonding accuracy of a combined substrate.

### Means for Solving the Problems

In one exemplary embodiment, a bonding apparatus includes a first holder, a second holder, a movable member and a motor. The first holder is configured to attract and hold a first substrate from above. The second holder is disposed below the first holder, and configured to attract and hold a second substrate from below. The movable member is configured to be linearly movable along a vertical direction, and also configured to press, with a tip end thereof, a central portion of the first substrate. The motor is configured to move the movable member along the vertical direction.

### Effect of the Invention

According to the exemplary embodiments, it is possible to improve the bonding accuracy of the combined substrate.

### BRIEF DESCRIPTION OF THE DRAWINGS

FIG. 1 is a schematic plan view illustrating a configuration of a bonding system according to a first exemplary embodiment.

FIG. 2 is a schematic side view of an upper wafer and a lower wafer according to the first exemplary embodiment.

FIG. 3 is a schematic plan view illustrating a configuration of a bonding apparatus according to the first exemplary embodiment.

FIG. 4 is a schematic side view illustrating the configuration of the bonding apparatus according to the first exemplary embodiment.

FIG. 5 is a schematic cross sectional view illustrating an upper chuck and a linear motion device according to the first exemplary embodiment.

FIG. 6 is a schematic cross sectional view of a striker according to the first exemplary embodiment.

FIG. 7 is a diagram illustrating an example of a tip end position of a pressing pin in a vertical direction and an elapsed time.

FIG. 8 is a flowchart illustrating a sequence of a processing performed by the bonding system according to the first exemplary embodiment.

FIG. 9 is a flowchart illustrating an example of a specific sequence of a processing described in a process S110.

FIG. 10 is a schematic diagram illustrating an example operation of the bonding system according to the first exemplary embodiment.

FIG. 11 is a schematic diagram illustrating an example operation of the bonding system according to the first exemplary embodiment.

FIG. 12 is a schematic diagram illustrating an example operation of the bonding system according to the first exemplary embodiment.

FIG. 13 is a schematic diagram illustrating an example operation of the bonding system according to the first exemplary embodiment.

FIG. 14 is a schematic diagram illustrating an example operation of a bonding system according to a second exemplary embodiment.

FIG. 15 is a schematic diagram illustrating an example operation of the bonding system according to the second exemplary embodiment.

FIG. 16 is a schematic diagram illustrating an example operation of the bonding system according to the second exemplary embodiment.

### DETAILED DESCRIPTION

Hereinafter, embodiments for a bonding apparatus, a bonding system, and a bonding method according to the present disclosure (hereinafter, referred to as “exemplary embodiments”) will be described in detail with reference to the accompanying drawings. Further, it should be noted that the present disclosure is not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “θ direction.”

Patent Document 1 discloses a technique of bonding a first substrate and a second substrate by pressing, using a striker, a central portion of the first substrate from above and bringing it into contact with the second substrate.

However, in the bonding apparatus described in Patent Document 1, there is a risk that the first substrate and the second substrate may be misaligned from their required positions due to, for example, an impact occurring upon contact between the striker and the central portion of the first substrate or an impact occurring upon contact between the first substrate and the second substrate. In this regard, there is a demand for a technique capable of reducing the occurrence of misalignment between the first substrate and the second substrate, thereby improving the bonding accuracy for the substrates.

### First Exemplary Embodiment

### <Configuration of Bonding System>

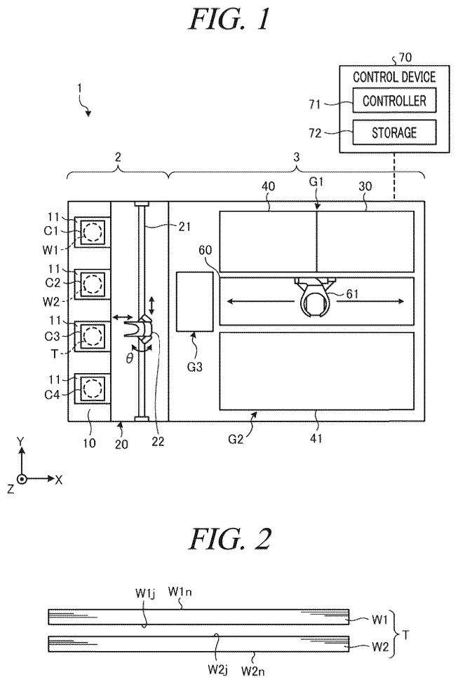

First, a configuration of a bonding system 1 according to a first exemplary embodiment will be explained with reference to FIG. 1 and FIG. 2. FIG. 1 is a schematic plan view illustrating a configuration of the bonding system 1 according to the first exemplary embodiment. FIG. 2 is a schematic side view of an upper wafer W1 and a lower wafer W2 according to the first exemplary embodiment.

The bonding system 1 shown in FIG. 1 is configured to bond a first substrate W1 and a second substrate W2 to form a combined wafer T.

The first substrate W1 and the second substrate W2 are semiconductor substrates, such as, but not limited to, silicon wafers or compound semiconductor wafers. The first substrate W1 and the second substrate W2 have approximately the same diameter.

Hereinafter, the first substrate W1 will be referred to as “upper wafer W1,” and the second substrate W2 will be referred to as “lower wafer W2.” That is, the upper wafer W1 is an example of a first substrate, and the lower wafer W2 is an example of a second substrate. Further, the upper wafer W1 and lower wafer W2 will sometimes be collectively referred to “wafer W.”

In addition, hereinafter, as illustrated in FIG. 2, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n.” Likewise, among plate surfaces of the lower wafer W2, the plate surface to be bonded to the upper wafer W1 will be referred to as “bonding surface W2j,” and the plate surface opposite to the bonding surface W2j will be referred to as “non-bonding surface W2n.”

As depicted in FIG. 1, the bonding system 1 is equipped with a carry-in/out station 2 and a processing station 3. The carry-in/out station 2 and the processing station 3 are arranged in this order along the positive X-axis direction. Also, the carry-in/out station 2 and the processing station 3 are connected as a single structure.

The carry-in/out station 2 includes a placement table 10 and a transfer section 20. The placement table 10 is equipped with a multiple number of placement plates 11. Provided on the placement plates 11 are cassettes C1, C2 and C3 each of which accommodates therein a plurality of (e.g., 25 sheets of) substrates horizontally. For example, the cassette C1 accommodates therein upper wafers W1; the cassette C2, lower wafers W2; and the cassettes C3, combined wafers T.

The transfer section 20 is provided adjacent to the positive X-axis side of the placement table 10. This transfer section 20 is provided with a transfer path 21 extending in the Y-axis direction and a transfer device 22 configured to be movable along this transfer path 21.

The transfer device 22 is configured to be movable in the X-axis direction as well as in the Y-axis direction and pivotable around the Z-axis. The transfer device 22 serves to transfer the upper wafers W1, the lower wafers W2, and the combined wafers T between the cassettes C1 to C3 placed on the placement plates 11 and a third processing block G3 of the processing station 3 to be described later.

Further, the number of the cassettes C1 to C3 disposed on the placement plates 11 is not limited to the shown example. Moreover, in addition to the cassettes C1, C2, and C3, a cassette for collecting a defective substrate may be disposed on the placement plate 11.

The processing station 3 has a plurality of processing blocks equipped with various types of devices, for example, three processing blocks G1, G2 and G3. For example, the first processing block G1 is provided on the front side (negative Y-axis side of FIG. 1) of the processing station 3, and the second processing block G2 is provided on the rear side (positive Y-axis side of FIG. 1) of the processing station 3. Further, the third processing block G3 is provided on the carry-in/out station 2 side (negative X-axis side of FIG. 1) of the processing station 3.

The first processing block G1 is equipped with a surface modifying apparatus 30 configured to modify the bonding surface W1j of the upper wafer W1 and the bonding surface W2j of the lower wafer W2. The surface modifying apparatus 30 cuts a SiO₂ bond in the bonding surfaces W1j and W2j of the upper and lower wafers W1 and W2 to form a single bond of SiO, thus modifying the bonding surfaces W1j and W2j so that they can be easily hydrophilized afterwards.

Further, a surface hydrophilizing apparatus 40 is disposed in the first processing block G1. The surface hydrophilizing apparatus 40 is configured to hydrophilize the bonding surfaces W1j and W2j of the upper and lower wafers W1 and W2 with, for example, pure water, and also serves to clean the bonding surfaces W1j and W2j.

In the surface hydrophilizing apparatus 40, while rotating the upper wafer W1 or the lower wafer W2 held by, for example, a spin chuck, the pure water is supplied onto the upper wafer W1 or the lower wafer W2. Accordingly, the pure water supplied onto the upper wafer W1 or the lower wafer W2 is diffused on the bonding surface W1j of the upper wafer W1 or the bonding surface W2j of the lower wafer W2, so that the bonding surfaces W1j and W2j are hydrophilized.

In the present exemplary embodiment, the surface modifying apparatus 30 and the surface hydrophilizing apparatus 40 are arranged horizontally. However, the surface hydrophilizing apparatus 40 may be stacked on or under the surface modifying apparatus 30.

The second processing block G2 includes a bonding apparatus 41. The bonding apparatus 41 is configured to bond the hydrophilized upper and lower wafers W1 and W2 by an intermolecular force. Details of this bonding apparatus 41 will be described later.

The third processing block G3 is equipped with a transition (TRS) device (not shown) for the upper wafer W1, the lower wafer W2, and the combined wafer T.

Further, as depicted in FIG. 1, a transfer section 60 is formed in an area surrounded by the first processing block G1, the second processing block G2, and the third processing block G3. A transfer device 61 is disposed in the transfer section 60. The transfer device 61 has a transfer arm configured to be movable in a vertical direction and a horizontal direction and pivotable around a vertical axis, for example.

This transfer device 61 is moved within the transfer section 60 to transfer the upper wafer W1, the lower wafer W2, and the combined wafer T to devices within the first processing block G1, the second processing block G2, and the third processing block G3 adjacent to the transfer section 60.

Further, the bonding system 1 is equipped with a control device 70. The control device 70 is configured to control an operation of the bonding system 1. This control device 70 is, for example, a computer, and has a controller 71 and a storage 72. The controller 71 includes a microcomputer having a central processing unit (CPU), a read only memory (ROM), a random access memory (RAM), input/output ports, etc., and various types of circuits. The CPU of such a microcomputer reads and executes a program stored in the ROM, thus implementing a control to be described later. Further, the storage 72 is implemented by, by way of non-limiting example, a semiconductor memory element such as a RAM or a flash memory, or a storage device such as a hard disk or an optical disk.

Additionally, such a program may have been recorded on a computer-readable recording medium, and may be installed from the recording medium into the storage 72 of the control device 70. The computer-readable recording medium may be, by way of non-limiting example, a hard disk (HD), a flexible disk (FD), a compact disk (CD), a magnet optical disk (MO), a memory card, or the like.

### <Configuration of Bonding Apparatus>

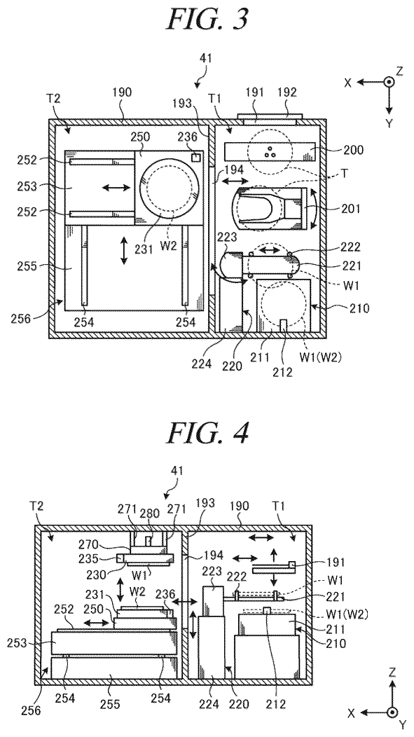

Now, a configuration of the bonding apparatus 41 will be explained with reference to FIG. 3 and FIG. 4. FIG. 3 is a schematic plan view illustrating the configuration of the bonding apparatus 41 according to the first exemplary embodiment, and FIG. 4 is a schematic side view showing the configuration of the bonding apparatus 41 according to the first exemplary embodiment.

As depicted in FIG. 3, the bonding apparatus 41 is equipped with a processing vessel 190 having a hermetically sealable inside. A carry-in/out opening 191 for the upper wafer W1, the lower wafer W2, and the combined wafer T is formed in a side surface of the processing vessel 190 on the side of the transfer section 60, and an opening/closing shutter 192 is provided at this carry-in/out opening 191.

The inside of the processing vessel 190 is partitioned into a transfer section T1 and a processing section T2 by an inner wall 193. The carry-in/out opening 191 described above is formed in the side surface of the processing vessel 190 in the transfer section T1. Further, the inner wall 193 is also provided with a carry-in/out opening 194 for the upper wafer W1, the lower wafer W2, and the combined wafer T.

In the transfer section T1, a transition device 200, a substrate transfer mechanism 201, an inverting mechanism 220, and a position adjusting mechanism 210 are arranged in this order from the carry-in/out opening 191 side, for example.

The transition device 200 temporarily places therein the upper wafer W1, the lower wafer W2, and the combined wafer T. The transition device 200 is formed in, for example, two levels, and is thus capable of placing therein any two of the upper wafer W1, the lower wafer W2, and the combined wafer T at the same time.

The substrate transfer mechanism 201 has a transfer arm configured to be movable in a vertical direction (Z-axis direction) and horizontal directions (X-axis direction and Y-axis direction) and pivotable around a vertical axis (θ direction), for example. The substrate transfer mechanism 201 is capable of transferring the upper wafer W1, the lower wafer W2, and the combined wafer T within the transfer section T1 or between the transfer section T1 and the processing section T2.

The position adjusting mechanism 210 is configured to adjust the direction of the upper wafer W1 and the lower wafer W2 in a horizontal direction. Specifically, the position adjusting mechanism 210 includes a base 211 equipped with a holder (not shown) configured to hold and rotate the upper and lower wafers W1 and W2, and a detector 212 configured to detect the positions of notches of the upper wafer W1 and the lower wafer W2. By detecting the positions of the notches of the upper wafer W1 and the lower wafer W2 through the use of the detector 212 while rotating the upper wafer W1 and the lower wafer W2 held by the base 211, the position adjusting mechanism 210 adjusts the positions of the notches. Accordingly, the direction of the upper wafer W1 and the lower wafer W2 in the horizontal direction is adjusted.

The inverting mechanism 220 is configured to invert front and rear surfaces of the upper wafer W1. Specifically, the inverting mechanism 220 has a holding arm 221 configured to hold the upper wafer W1. The holding arm 221 extends in a horizontal direction (X-axis direction). Further, the holding arm 221 is provided with holding members 222 for holding the upper wafer W1 at, for example, four positions thereon.

The holding arm 221 is supported by a driver 223 equipped with, for example, a motor. The holding arm 221 is rotatable around a horizontal axis by this driver 223. Further, the holding arm 221 is also rotatable about the driver 223 and movable in a horizontal direction (X-axis direction). Below the driver 223, another driver (not shown) provided with, for example, a motor is provided. The driver 223 can be moved in a vertical direction by this other driver along a supporting column 224 that extends in the vertical direction.

In this way, the upper wafer W1 held by the holding members 222 can be rotated around the horizontal axis by the driver 223, and can also be moved in the vertical and horizontal directions. Further, the upper wafer W1 held by the holding members 222 can be moved between the position adjusting mechanism 210 and an upper chuck 230 to be described later by being rotated about the driver 223.

Provided in the processing section T2 are the upper chuck 230 configured to attract and hold a top surface (non-bonding surface W1n) of the upper wafer W1 from above and a lower chuck 231 configured to attract and hold a bottom surface (non-bonding surface W2n) of the lower wafer W2 from below. The lower chuck 231 is disposed below the upper chuck 230, and is configured to face the upper chuck 230. The upper chuck 230 is an example of a first holder, and the lower chuck 231 is an example of a second holder.

The upper chuck 230 is, for example, a vacuum chuck, and is connected to a suction device such as a non-illustrated vacuum pump or the like. The upper chuck 230 vacuum-suctions the upper wafer W1, which is located on an attraction surface (a bottom surface of the upper chuck 230), by using a suction force generated by the suction device, thus attracting and holding the upper wafer W1 from above. A specific configuration of the upper chuck 230 will be described later.

As depicted in FIG. 4, the upper chuck 230 is supported by a supporting member 270 provided above the upper chuck 230. The supporting member 270 is fixed to a ceiling surface of the processing vessel 190 with, for example, a plurality of supporting columns 271 therebetween. A linear motion device 280 is disposed above the supporting member 270. The linear motion device 280 includes a striker configured to press a central portion of the upper wafer W1 held by the upper chuck 230, and a delivery device configured to receive the upper wafer W1 from the transfer device 61 and hand it over to the upper chuck 230. A specific configuration of the linear motion device 280 will be elaborated later.

An upper imaging device 235 configured to image a top surface (bonding surface W2j) of the lower wafer W2 held by the lower chuck 231 is provided at a lateral side of the upper chuck 230. The upper imaging device 235 may be, for example, a CCD camera. The upper imaging device 235 is an example of an imaging device.

The lower chuck 231 is, for example, a vacuum chuck, and is connected to a suction device such as a non-illustrated vacuum pump or the like. The lower chuck 231 vacuum-suctions the lower wafer W2, which is located on an attraction surface (a top surface of the lower chuck 231), by using a suction force generated by the suction device, thereby attracting and holding the lower wafer W2 from below.

The lower chuck 231 is supported by a first mover 250 disposed below the lower chuck 231. The first mover 250 serves to move the lower chuck 231 in a horizontal direction (X-axis direction) as will be described later. Further, the first mover 250 is configured to be able to move the lower chuck 231 in a vertical direction and to rotate the lower chuck 231 around a vertical axis.

The first mover 250 is provided with a lower imaging device 236 configured to image a bottom surface (bonding surface W1j) of the upper wafer W1 held by the upper chuck 230. The lower imaging device 236 may be, for example, a CCD camera. The lower imaging device 236 is an example of an imaging device.

The first mover 250 is mounted to a pair of rails 252. The rails 252 are disposed at a bottom surface side of the first mover 250, and is elongated in a horizontal direction (X-axis direction). The first mover 250 is configured to be movable along the rails 252.

The pair of rails 252 are mounted to a second mover 253. The second mover 253 is mounted to a pair of rails 254. The rails 254 are provided on a bottom surface side of the second mover 253, and is elongated in a horizontal direction (Y-axis direction). The second mover 253 is configured to be movable in the horizontal direction (Y-axis direction) along the rails 254. Further, the pair of rails 254 are disposed on a placement table 255 which is provided on a bottom surface of the processing vessel 190.

The first mover 250, the second mover 253, and the like constitute a position aligning device 256. The position aligning device 256 moves the lower chuck 231 in the X-axis direction, the Y-axis direction, and the θ direction, thus allowing the upper wafer W1 held by the upper chuck 230 and the lower wafer W2 held by the lower chuck 231 to be aligned in the horizontal direction. In addition, the position aligning device 256 moves the lower chuck 231 in the Z-axis direction as well, thus allowing the upper wafer W1 held by the upper chuck 230 and the lower wafer W2 held by the lower chuck 231 to be aligned in the vertical direction as well.

Here, although the lower chuck 231 is moved in the X-axis direction, the Y-axis direction, and the θ direction, the position aligning device 256 may be configured to move the lower chuck 231 in the X-axis direction and the Y-axis direction and move the upper chuck 230 in the θ direction, for example. Further, although the lower chuck 231 is moved in the Z-axis direction in the present exemplary embodiment, the position aligning device 256 may be configured to move the upper chuck 230 in the Z-axis direction, for example.

### <Configuration of Upper Chuck and Linear Motion Device>

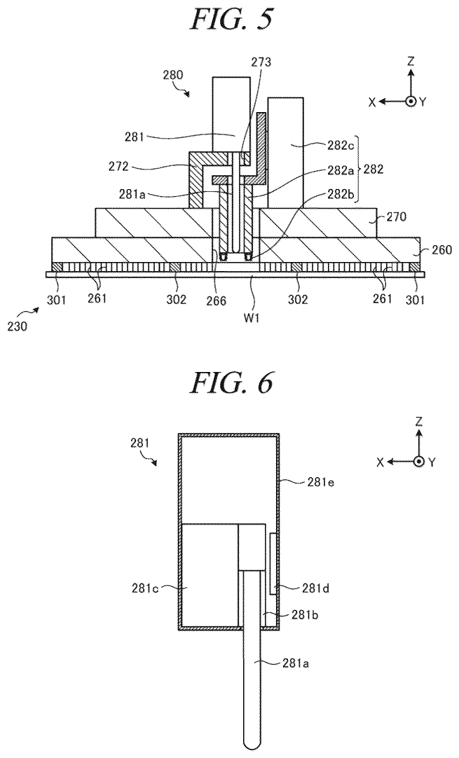

Now, a configuration example of the upper chuck 230 and the linear motion device 280 will be explained with reference to FIG. 5. FIG. 5 is a schematic cross sectional view of the upper chuck 230 and the liner motion device 280 according to the first exemplary embodiment. For ease of understating, the lower imaging device 236 is not illustrated in FIG. 5.

As depicted in FIG. 5, the upper chuck 230 has a main body 260. The main body 260 is supported by the supporting member 270. The supporting member 270 and the main body 260 are provided with a through hole 266 that is formed through the supporting member 270 and the main body 260 in the vertical direction. The through hole 266 is positioned to correspond to the central portion of the upper wafer W1 attracted to and held by the upper chuck 230. A cylindrical member 282a, which will be described later, is inserted through this through hole 266.

A plurality of pins 261 to be brought into contact with the top surface (non-bonding surface W1n) of the upper wafer W1 is provided on a bottom surface of the main body 260. Each of these pins 261 has a diameter of, e.g., 0.1 mm to 1 mm and a height of several tens of μm to several hundreds of μm. The plurality of pins 261 are evenly arranged at a distance of, e.g., 2 mm.

Further, multiple outer attraction members 301 and multiple inner attraction members 302 for attracting the upper wafer W1 by vacuum suction are provided in the bottom surface of the main body 260. The multiple outer attraction members 301 and the multiple inner attraction members 302 have, for example, arc-shaped attraction regions when viewed from the top. Also, the multiple outer attraction members 301 and the multiple inner attraction members 302 have the same height as the pins 261.

The multiple outer attraction members 301 are arranged at an outer periphery of the main body 260 along a circumferential direction thereof. The multiple outer attraction members 301 are connected to a non-illustrated suction device such as a vacuum pump, and attracts an outer periphery of the upper wafer W1 by vacuum suction.

The multiple inner attraction members 302 are arranged along the circumferential direction on a radially inner side of the main body 260 relative to the multiple outer attraction members 301. The inner attraction members 302 are connected to a non-illustrated suction device such as a vacuum pump, and attracts a region between the outer periphery and the central portion of the upper wafer W1 by vacuum suction.

As depicted in FIG. 5, the linear motion device 280 is equipped with a striker 281 and a delivery device 282.

The striker 281 is equipped with a pressing pin 281a. The pressing pin 281a is a cylindrical member extending in the vertical direction, and is inserted through a through hole 273 of a support 272 to be described later and the cylindrical member 282a.

The bonding apparatus 41 according to the first exemplary embodiment presses the central portion of the upper wafer W1 attracted to and held by the upper chuck 230 with a tip end of the pressing pin 281a to bring it into contact with the lower wafer W2. As a result, a bonding wave is generated between the upper wafer W1 and the lower wafer W2, whereby a bonding region gets expanded from the central portions of the upper and lower wafers W1 and wafer W2 toward the outer peripheries thereof. Finally, the entire bonding surface W1j of the upper wafer W1 and the entire bonding surface W2j of the lower wafer W2 come into contact with each other to thereby form the combined wafer T.

However, if an impact is large when the pressing pin 281a comes into contact with the central portion of the upper wafer W1 or when the upper wafer W1 comes into contact with the lower wafer W2, the upper wafer W1 and the lower wafer W2 may be misaligned from their required positions. This positional misalignment between the upper wafer W1 and the lower wafer W2 may lead to deterioration in the bonding accuracy of the combined wafer T. For this reason, it is desirable to suppress the positional misalignment between the upper wafer W1 and the lower wafer W2.

To this end, in the bonding apparatus 41 according to the first exemplary embodiment, a motor is used as a driving source for the pressing pin 281a, making it possible to control the movement of the pressing pin 281a. This allows for the control over the movement of the pressing pin 281a to minimize the impact when the pressing pin 281a comes into contact with the central portion of the upper wafer W1 or when the upper wafer W1 comes into contact with the lower wafer W2. Therefore, the bonding apparatus 41 according to the first exemplary embodiment can effectively suppress the positional misalignment between the upper wafer W1 and the lower wafer W2, thereby improving the bonding accuracy of the combined wafer T. A specific configuration of the striker 281 will be described later.

The delivery device 282 includes the cylindrical member 282a, multiple attraction members 282b, and a linearly moving mechanism 282c. The cylindrical member 282a is a tubular member that is inserted through the through hole 266 of the upper chuck 230. The multiple attraction members 282b are provided at an end portion of the cylindrical member 282a. The multiple attraction members 282b attract the upper wafer W1 by vacuum suction. The linearly moving mechanism 282c moves the cylindrical member 282a vertically by, for example, a driver having a motor embedded therein.

The delivery device 282 receives the upper wafer W1 from the inverting mechanism 220 of the bonding apparatus 41 by using the attraction members 282b, and then raises the cylindrical member 282a by using the linearly moving mechanism 282c, thus allowing the upper wafer W1 to be handed over to the upper chuck 230.

### <Configuration of Striker>

Now, the configuration of the striker 281 will be explained with reference to FIG. 6. FIG. 6 is a schematic cross sectional view of the striker 281 according to the first exemplary embodiment.

As shown in FIG. 6, the striker 281 includes the pressing pin 281a, a guide 281b, a motor 281c, and a position sensor 281d. The pressing pin 281a (more precisely, a portion of the pressing pin 281a), the guide 281b, the motor 281c, and the position sensor 281d are accommodated in a rectangular housing 281e. The housing 281e is supported by the support 272. The support 272 is fixed to, for example, a top surface of the supporting member 270. Specifically, the support 272 has a leg portion vertically extending from the top surface of the supporting member 270 and a support portion horizontally extending from an upper end of the leg portion toward the through hole 266. The housing 281e is provided on the support portion of the support 272 so as to be positioned above the through hole 266. The cylindrical member 282a of the delivery device 282 is located below the support portion of the support 272 and is moved up and down within a range in which it does not interfere with the support portion. The through hole 273 is formed through the support 272 in the vertical direction. The pressing pin 281a is inserted through this through hole 273.

The pressing pin 281a is a cylindrical member that extends vertically. The pressing pin 281a is configured to be linearly movable along the vertical direction via the guide 281b, which will be described later. Specifically, the pressing pin 281a is configured to be movable between a standby position, a pre-contact position, a contact position, and a bonding position, which will be described later. The tip end of the pressing pin 281a is exposed from an opening provided at a side surface of the housing 281e. The pressing pin 281a is an example of a movable member.

The guide 281b is, by way of example, a linear guide, and extends vertically. The guide 281b is fixed to the housing 281e.

The motor 281c is, for example, a linear motor. The motor 281c as such a linear motor may be, by way of non-limiting example, a voice coil motor. The motor 281c moves the pressing pin 281a vertically along the guide 281b. The motor 281c is fixed to the housing 281e.

The position sensor 281d is, by way of example, a linear encoder. The position sensor 281d is fixed to the housing 281e, and serves to detect the position of pressing pin 281a in the vertical direction.

The striker 281 configured as described above moves the pressing pin 281a along the vertical direction by using the motor 281c, and presses the central portion of the upper wafer W1, which is attracted to and held by the upper chuck 230, with the tip end of the pressing pin 281a to bring it into contact with the lower wafer W2. The striker 281 may be configured to be operated with a preset thrust.

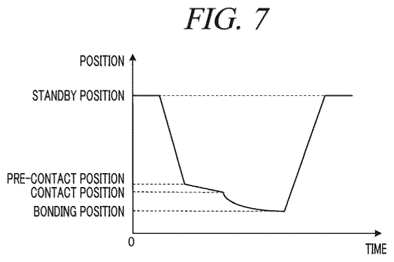

Here, referring to FIG. 7, a control method for the striker 281 by the controller 71 according to the first exemplary embodiment will be explained. FIG. 7 is a diagram showing an example of the position of the tip end of the pressing pin 281a in the vertical direction and an elapsed time.

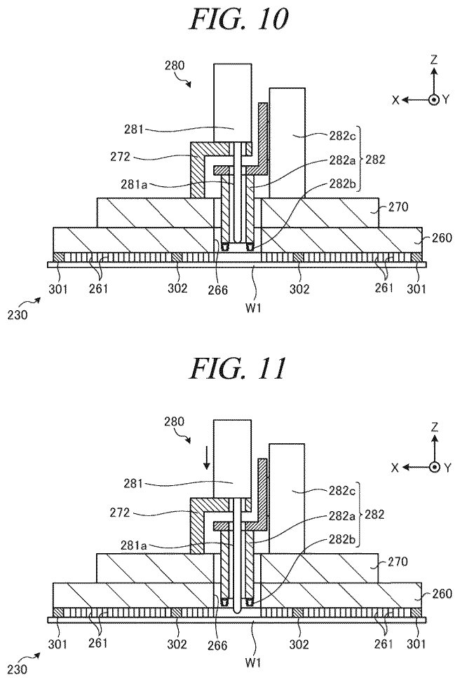

First, the controller 71 controls the motor 281c to move the pressing pin 281a from the standby position to the pre-contact position at a first speed. Here, the standby position is a position spaced apart from the upper wafer W1. Specifically, the standby position is a position higher than the height position of the top surface of the upper wafer W1 (higher than the tip end position of the pin 261) (see FIG. 10). The pre-contact position is a position closer to the upper wafer W1 than the standby position but is a position where the tip end of the pressing pin 281a is not in contact with the upper wafer W1 (see FIG. 11).

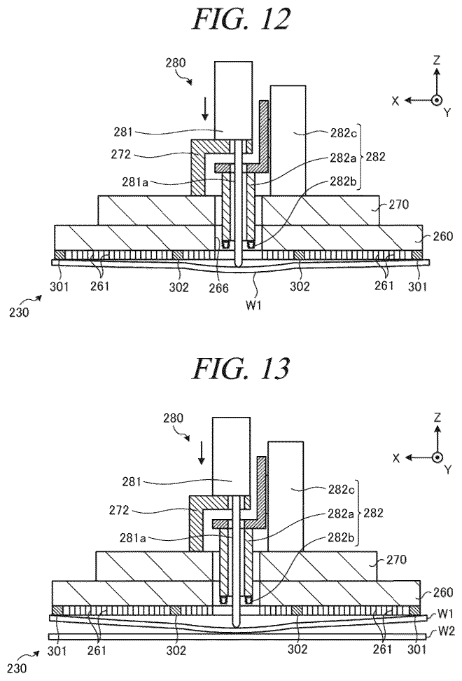

Next, the controller 71 controls the motor 281c to move the pressing pin 281a from the pre-contact position to the contact position at a second speed lower than the first speed. Here, the contact position is a position where the tip end of the pressing pin 281a comes into contact with the upper wafer W1. To elaborate, the contact position is a position that causes the central portion of the upper wafer W1 to be bent (see FIG. 12). In other words, the contact position is a position lower than the height position of the top surface of the upper wafer W1 (lower than the tip end position of the pin 261).

In this way, the controller 71 controls the position and the speed of the motor 281c to move the pressing pin 281a from the standby position to the contact position. Further, the controller 71 is also capable of controlling the position of the pressing pin 281a based on a detection result from the position sensor 281d (position control). Furthermore, the controller 71 is capable of controlling the moving speed of the pressing pin 281a by controlling an electric current supplied to the motor 281c (speed control).

Thereafter, the controller 71 moves the pressing pin 281a from the contact position to the bonding position. Here, the bonding position is a position lower than the contact position, where the central portion of the upper wafer W1 and the lower wafer W2 come into contact with each other (see FIG. 13).

The controller 71 performs a thrust control of the motor 281c to move the pressing pin 281a from the contact position to the bonding position. By way of example, the striker 281 is provided with a detector (not shown) such as a torque sensor for detecting the thrust of the motor 281c. The thrust control is a control method that controls the thrust of the motor 281c by varying the electric current supplied to the motor 281c. Specifically, the controller 71 varies the electric current supplied to the motor 281c based on a detection result of the non-illustrated detector so that the thrust of the motor 281c, in other words, the magnitude of the force received by the pressing pin 281a becomes a preset value. That is, the bonding position is a position where the magnitude of the force applied to the pressing pin 281a reaches the preset value. Thereafter, the controller 71 moves the striker 281 to the standby position.

### <Specific Operation of Bonding System>

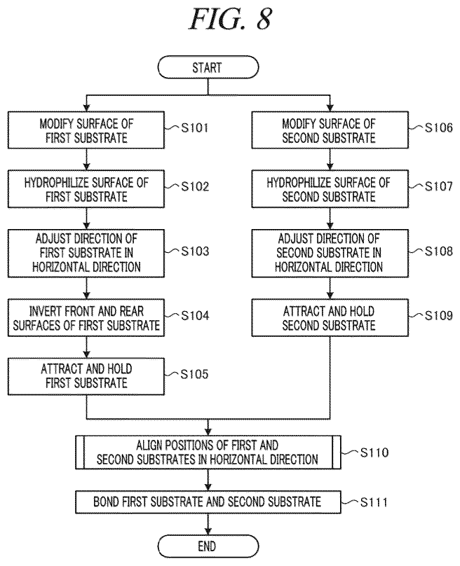

Now, a specific operation of the bonding system 1 according to the first exemplary embodiment will be explained with reference to FIG. 8. FIG. 8 is a flowchart illustrating a sequence of a processing performed by the bonding system 1 according to the exemplary embodiment. Various processes shown in FIG. 8 are controlled under the control of the control device 70.

First, the cassette C1 accommodating therein a plurality of upper wafers W1, the cassette C2 accommodating therein a plurality of lower wafers W2, and the empty cassette C3 are placed on the preset placement plates 11 of the carry-in/out station 2. Then, the upper wafer W1 is taken out of the cassette C1 by the transfer device 22, and transferred to the transition device disposed in the third processing block G3.

Next, the upper wafer W1 is transferred to the surface modifying apparatus 30 of the first processing block G1 by the transfer device 61. In the surface modifying apparatus 30, an oxygen gas as a processing gas is excited into plasma under a preset decompressed atmosphere to be ionized. The oxygen ions are radiated to the bonding surface of the upper wafer W1, so that the bonding surface is plasma-processed. As a result, the bonding surface of the upper wafer W1 is modified (process S101).

Subsequently, the upper wafer W1 is transferred to the surface hydrophilizing apparatus 40 of the first processing block G1 by the transfer device 61. In the surface hydrophilizing apparatus 40, while rotating the upper wafer W1 held by the spin chuck, pure water is supplied onto the upper wafer W1. As a result, the bonding surface of the upper wafer W1 is hydrophilized. Further, the bonding surface of the upper wafer W1 is also cleaned by the pure water (process S102).

Next, the upper wafer W1 is transferred to the bonding apparatus 41 of the second processing block G2 by the transfer device 61. The upper wafer W1 carried into the bonding apparatus 41 is transferred to the position adjusting mechanism 210 via the transition device 200, and the direction of the upper wafer W1 in the horizontal direction is adjusted by the position adjusting mechanism 210 (process S103).

Thereafter, the upper wafer W1 is delivered from the position adjusting mechanism 210 to the inverting mechanism 220, and the front and rear surfaces of the upper wafer W1 are inverted by the inverting mechanism 220 (process S104). To be specific, the bonding surface W1j of the upper wafer W1 is turned to face downwards. Subsequently, the upper wafer W1 is transferred from the inverting mechanism 220 to the upper chuck 230, and the upper wafer W1 is attracted to and held by the upper chuck 230 (process S105).

In parallel with the processes S101 to S105 upon the upper wafer W1, the lower wafer W2 is also processed. First, the lower wafer W2 is taken out of the cassette C2 by the transfer device 22, and transferred to the transition device disposed in the third processing block G3.

Next, the lower wafer W2 is transferred to the surface modifying apparatus 30 by the transfer device 61, and the bonding surface W2j of the lower wafer W2 is modified (process S106). Thereafter, the lower wafer W2 is transferred to the surface hydrophilizing apparatus 40 by the transfer device 61, and the bonding surface W2j of the lower wafer W2 is hydrophilized and cleaned (process S107).

Afterwards, the lower wafer W2 is transferred to the bonding apparatus 41 by the transfer device 61. The lower wafer W2 carried into the bonding apparatus 41 is transferred to the position adjusting mechanism 210 via the transition device 200. Then, the direction of the lower wafer W2 in the horizontal direction is adjusted by the position adjusting mechanism 210 (process S108).

Thereafter, the lower wafer W2 is transferred to the lower chuck 231, and is attracted to and held by the lower chuck 231 with the notch thereof directed toward a predetermined direction (process S109).

Subsequently, position alignment in the horizontal direction between the upper wafer W1 held by the upper chuck 230 and the lower wafer W2 held by the lower chuck 231 is carried out (process S110). This process S111 will be elaborated later.

Then, the lower wafer W2 is raised by using the first mover 250 to bond the upper wafer W1 and the lower wafer W2 (process S111). Specifically, after raising the lower wafer W2, the controller 71 moves the pressing pin 281a from the contact position to the bonding position by using the thrust to bring the central portion of the upper wafer W1 into contact with a central portion of the lower wafer W2, thereby bonding the upper wafer W1 and the lower wafer W2 together (see FIG. 13).

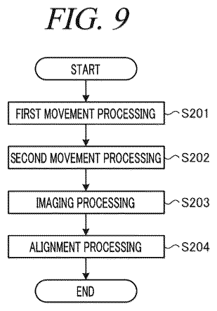

Now, an example of a specific sequence of the position alignment between the upper wafer W1 and the lower wafer W2 in the horizontal direction in the process S110 will be explained with reference to FIG. 9 to FIG. 13. FIG. 9 is a flowchart showing an example of a specific sequence of a processing described in the process S110. FIG. 10 to FIG. 13 are schematic diagrams illustrating example operations of the bonding system 1 according to the first exemplary embodiment.

As shown in FIG. 9, the controller 71 first performs a first movement processing (process S201). In the first movement processing, the controller 71 controls the motor 281c of the striker 281 (position control and speed control) to move the pressing pin 281a from the standby position to the pre-contact position at the first speed (see FIG. 10 and FIG. 11).

Subsequently, the controller 71 performs a second movement processing (process S202). In the second movement process, the controller 71 controls the motor 281c of the striker 281 (position control and speed control) to move the pressing pin 281a from the pre-contact position to the contact position at the second speed which is lower than the first speed (see FIG. 12).

Next, the controller 71 performs an imaging processing (process S203). In the imaging processing, the controller 71 images the bonding surface W2j of the lower wafer W2 or the bonding surface W1j of the upper wafer W1 by using the upper imaging device 235 or the lower imaging device 236, respectively.

Subsequently, the controller 71 performs an alignment processing (process S204). In the alignment processing, the controller 71 controls the position aligning device 256 based on the imaging result from the imaging processing to align the positions of the upper wafer W1 and the lower wafer W2 in the horizontal direction.

As described above, the controller 71 controls the motor 281c of the striker 281 to make the moving speed of the pressing pin 281a from the pre-contact position to the contact position lower than the moving speed of the pressing pin 281a from the standby position to the pre-contact position. As a result of this, the impact generated when the tip end of the pressing pin 281a comes into contact with the central portion of the upper wafer W1 can be reduced, thereby making the misalignment of the upper wafer W1 less likely to occur.

After controlling the motor 281c to move the pressing pin 281a from the standby position to the contact position, the controller 71 images the bonding surface W2j of the lower wafer W2 or the bonding surface W1j of the upper wafer W1 by using the upper imaging device 235 or the lower imaging device 236. Thereafter, the controller 71 controls the position aligning device 256 based on the imaging result from the imaging processing to align the positions of the lower wafer W2 and the lower wafer W2 in the horizontal direction. That is, the controller 71 performs the imaging processing, with the central portion of the upper wafer W1 bent. According to this processing, even if the upper wafer W1 is misaligned when the pressing pin 281a comes into contact with the central portion of the upper wafer W1, this misalignment can be corrected in the subsequent imaging processing and alignment processing.

As stated above, the bonding apparatus 41 according to the first exemplary embodiment is provided with the motor 281c configured to move the pressing pin 281a in the vertical direction, thereby making it possible to control the movement of the pressing pin 281a. This allows the movement of the pressing pin 281a to be controlled, and the impact occurring when the pressing pin 281a comes into contact with the central portion of the upper wafer W1 or when the upper wafer W1 comes into contact with the lower wafer W2 can be reduced. Therefore, the bonding apparatus 41 according to the first exemplary embodiment can effectively suppress the positional misalignment between the upper wafer W1 and the lower wafer W2, thereby improving the bonding accuracy of the combined wafer T.

### Second Exemplary Embodiment

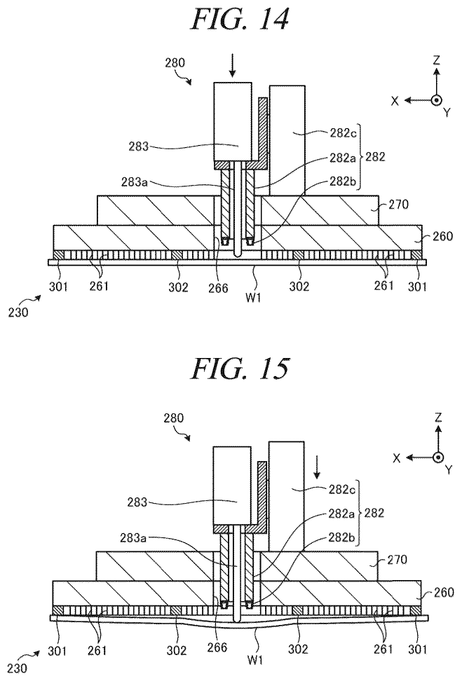

FIG. 14 to FIG. 16 are schematic diagrams illustrating an example operation of the bonding system 1 according to a second exemplary embodiment. In the first exemplary embodiment described above, the controller 71 controls the speed and the position of the pressing pin 281a by using the motor 281c of the striker 281. However, without being limited thereto, the controller 71 may perform the control over the speed and the position of the pressing pin by using a motor of the delivery device 282.

In this case, as illustrated in FIG. 14, a striker 283 is fixed to the delivery device 282. The controller 71 moves the cylindrical member 282a of the delivery device 282 along the vertical direction by using the linearly moving mechanism 282c having a motor (not shown) embedded therein, thereby allowing the striker 283 fixed to the delivery device 282 to be moved along the vertical direction. The linearly moving mechanism 282c may include, by way of example, a rotary motor and a ball screw.

In addition, the striker 283 according to the second exemplary embodiment includes a pressing pin 283a and an actuator (not shown) configured to support the pressing pin 283a. The actuator generates a constant pressure in a specific direction (here, in a vertically downward direction) by air supplied from, for example, an electro-pneumatic regulator (not shown). The actuator is capable of controlling a pressing load, which is applied to the central portion of the upper wafer W1 upon the contact with the upper wafer W1, by the air supplied from the electro-pneumatic regulator. Further, the actuator of the striker 283 can move the pressing pin 283a between an up-position, where a tip end of the pressing pin 283a is located inside the cylindrical member 282a of the delivery device 282, and a down-position (see FIG. 14), where the tip end is located vertically below the attraction members 282b of the delivery device 282.

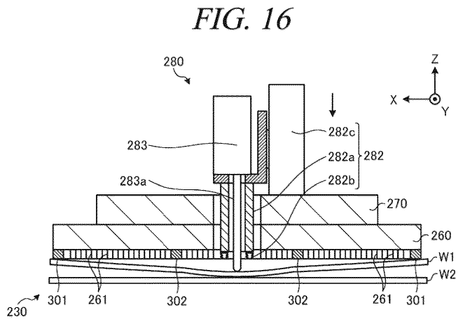

In the bonding processing, the controller 71 controls the actuator of the striker 283 to move the tip end of the pressing pin 283a from the up-position to the down-position (see FIG. 14). The controller 71 then controls the motor of the delivery device 282 (position control and speed control) to move the pressing pin 283a to the contact position (see FIG. 15). Thereafter, the controller 71 controls the motor of the delivery device 282 (position control and speed control) to move the pressing pin 283a from the contact position to the bonding position. At this time, the controller 71 controls the pressing load of the pressing pin 283a on the upper wafer W1 by the actuator. As a result, the striker 283 presses the central portion of the upper wafer W1, which is attracted to and held by the upper chuck 230, and brings it into contact with the lower wafer W2 (see FIG. 16).

As stated above, according to the bonding apparatus 41 of the second exemplary embodiment, even if the striker 283 does not have a motor, the speed and the position of the striker 283 can still be controlled by using the motor of the delivery device 282. In other words, the speed control and the position control over the striker 283 can be carried out with a simpler configuration.

The present disclosure may adopt the following configurations.

(1)

A bonding apparatus, including:
a first holder configured to attract and hold a first substrate from above;
a second holder disposed below the first holder, and configured to attract and hold a second substrate from below;
a movable member configured to be linearly movable along a vertical direction, and also configured to press, with a tip end thereof, a central portion of the first substrate; and
a motor configured to move the movable member along the vertical direction.
   (2)

The bonding apparatus described in (1),
wherein the motor is a linear motor.
   (3)

The bonding apparatus described in (1) or (2), further including:
a controller configured to control the motor to move the movable member between a standby position spaced apart from the first substrate, a pre-contact position that is closer to the first substrate than the standby position and where the movable member is not in contact with the first substrate, and a contact position where the movable member comes into contact with the first substrate,
wherein the controller controls the motor to make a moving speed of the movable member from the pre-contact position to the contact position lower than a moving speed of the movable member from the standby position to the pre-contact position.
   (4)

The bonding apparatus described in (1), further including:
an imaging device configured to image a bonding surface of the first substrate held by the first holder or the second substrate held by the second holder;
a position aligning device configured to perform positional alignment of the first substrate held by the first holder or the second substrate held by the second holder in a horizontal direction; and
a controller configured to control the motor to move the movable member between a standby position spaced apart from the first substrate and a contact position where the movable member comes into contact with the first substrate,
wherein the controller controls the motor to move the movable member from the standby position to the contact position, images the bonding surface of the first substrate or the second substrate by using the imaging device, and performs positional alignment between the first substrate and the second substrate in the horizontal direction by controlling the position aligning device based on an imaging result from the imaging device.
   (5)

The bonding apparatus described in (3) or (4),
wherein the contact position is a position that causes the central portion of the first substrate to be bent.
   (6)

The bonding apparatus described in (3) or (4),
wherein the controller controls a thrust of the motor to move the movable member from the contact position to a bonding position where the central portion of the first substrate and the second substrate come into contact with each other.
   (7)

A bonding system, including:
a surface modifying apparatus configured to modify surfaces of a first substrate and a second substrate;
a surface hydrophilizing apparatus configured to hydrophilize the modified surfaces of the first substrate and the second substrate; and
a bonding apparatus configured to bond the hydrophilized first and second substrates together by an intermolecular force,
wherein the bonding apparatus includes:
a first holder configured to attract and hold the first substrate from above;
a second holder disposed below the first holder, and configured to attract and hold the second substrate from below; and
a striker configured to press a central portion of the first substrate into contact with the second substrate, and
the striker includes:
a guide extending in a vertical direction;
a pressing member configured to be linearly moved along the guide; and
a motor configured to move the pressing member along the guide.
   (8)

A bonding method, including:
attracting and holding a first substrate by using a first holder configured to attract and hold the first substrate from above;
attracting and holding a second substrate by using a second holder that is disposed below the first holder and configured to attract and hold the second substrate from below; and
by using a motor configured to move a movable member, which is configured to be linearly moved along a vertical direction and also configured to press, with a tip end thereof, a central portion of the first substrate, moving the movable member between a standby position spaced apart from the first substrate, a pre-contact position that is closer to the first substrate than the standby position and where the movable member is not in contact with the first substrate, and a contact position where the movable member comes into contact with the first substrate,
wherein, in the moving of the movable member, a moving speed of the movable member from the pre-contact position to the contact position is lower than a moving speed of the movable member from the standby position to the pre-contact position.
   (9)

A bonding method, including:
attracting and holding a first substrate by using a first holder configured to attract and hold the first substrate from above;
attracting and holding a second substrate by using a second holder that is disposed below the first holder and configured to attract and hold the second substrate from below;
by using a motor configured to move a movable member, which is configured to be linearly moved along a vertical direction and also configured to press, with a tip end thereof, a central portion of the first substrate, moving the movable member between a standby position spaced apart from the first substrate and a contact position where the movable member comes into contact with the first substrate;
imaging a bonding surface of the first substrate held by the first holder or the second substrate held by the second holder by using an imaging device configured to image the bonding surface of the first substrate or the second substrate; and
by using a position aligning device configured to perform positional alignment of the first substrate held by the first holder or the second substrate held by the second holder in a horizontal direction, performing the positional alignment between the first substrate and the second substrate in the horizontal direction based on an imaging result from the imaging device.

It should be noted that the above-described exemplary embodiment is illustrative in all aspects and is not anyway limiting. In fact, the above-described exemplary embodiment can be embodied in various forms. The above-described exemplary embodiment may be omitted, replaced and modified in various ways without departing from the scope and the spirit of claims.

### EXPLANATION OF CODES

1: Bonding system
30: Surface modifying apparatus
40: Surface hydrophilizing apparatus
41: Bonding apparatus
70: Control device
71: Controller
230: Upper chuck
231: Lower chuck
235: Upper imaging device
236: Lower imaging device
250: First mover
253: Second mover
255: Placement table
256: Position aligning device
260: Main body
266: Through hole
270: Supporting member
280: Linear motion device
281: Striker
281a: Pressing pin
281c: Motor
282: Delivery device

1. A bonding apparatus, comprising:
a first holder attracting and holding a first substrate from above;
a second holder disposed below the first holder, and attracting and holding a second substrate from below;
a movable member linearly movable along a vertical direction, and also pressing, with a tip end thereof, a central portion of the first substrate; and
a motor moving the movable member along the vertical direction.

2. The bonding apparatus of claim 1,
wherein the motor is a linear motor.

3. The bonding apparatus of claim 1, further comprising:
controller circuitry configured to:
control the motor to move the movable member between a standby position spaced apart from the first substrate, a pre-contact position that is closer to the first substrate than the standby position and where the movable member is not in contact with the first substrate, and a contact position where the movable member comes into contact with the first substrate, and
control the motor to make a moving speed of the movable member from the pre-contact position to the contact position lower than a moving speed of the movable member from the standby position to the pre-contact position.

4. The bonding apparatus of claim 1, further comprising:
an imaging device imaging a bonding surface of the first substrate held by the first holder or the second substrate held by the second holder;
a position aligning device performing positional alignment of the first substrate held by the first holder or the second substrate held by the second holder in a horizontal direction; and
controller circuitry configured to:
control the motor to move the movable member between a standby position spaced apart from the first substrate and a contact position where the movable member comes into contact with the first substrate, and
control the motor to move the movable member from the standby position to the contact position, image the bonding surface of the first substrate or the second substrate by using the imaging device, and perform positional alignment between the first substrate and the second substrate in the horizontal direction by controlling the position aligning device based on an imaging result from the imaging device.

5. The bonding apparatus of claim 4,
wherein the contact position is a position that causes the central portion of the first substrate to be bent.

6. The bonding apparatus of claim 3,
wherein the controller circuitry is configured to control a thrust of the motor to move the movable member from the contact position to a bonding position where the central portion of the first substrate and the second substrate come into contact with each other.

7. (canceled)

8. A bonding method, comprising:
attracting and holding a first substrate from above the first holder by using a first holder;
attracting and holding a second substrate by using a second holder that is disposed below the first holder; and
by using a motor, linearly moved moving the movable member between a standby position spaced apart from the first substrate, a pre-contact position that is closer to the first substrate than the standby position and where the movable member is not in contact with the first substrate, and a contact position where the movable member comes into contact with the first substrate, the motor being linearly moved along a vertical direction and pressing, with a tip end of the motor, a central portion of the first substrate,
wherein, in the moving of the movable member, a moving speed of the movable member from the pre-contact position to the contact position is lower than a moving speed of the movable member from the standby position to the pre-contact position.

9. A bonding method, comprising:
attracting and holding a first substrate from above the first substrate by using a first holder;
attracting and holding a second substrate by using a second holder that is disposed below the first holder;
by using a motor, moving the movable member between a standby position spaced apart from the first substrate and a contact position where the movable member comes into contact with the first substrate, the motor being linearly moved along a vertical direction and pressing, with a tip end of the motor, a central portion of the first substrate;
imaging a bonding surface of the first substrate held by the first holder or the second substrate held by the second holder by using an imaging device; and
by using a position aligning device, performing the positional alignment between the first substrate and the second substrate in the horizontal direction based on an imaging result from the imaging device.

10. A bonding system comprising:
the bonding apparatus according to claim 1;
a surface modifying apparatus modifying a bonding surface of the first substrate and a bonding surface of the second substrate;
a surface hydrophilizing apparatus hydrophilizing the modified bonding surfaces with pure water; and
a transfer device transferring the first substrate and the second substrate.

11. The bonding system according to claim 10, further comprising a carry-in/out station holding cassettes accommodating substrates.

12. The bonding system according to claim 10, further comprising control circuitry configured to control the motor of the bonding apparatus.

13. The bonding system according to claim 10, wherein the surface modifying apparatus generates plasma to modify the bonding surfaces.

14. The bonding system according to claim 10, wherein the surface hydrophilizing apparatus supplies pure water to the bonding surfaces while rotating the first substrate or the second substrate.

15. The bonding system according to claim 10, wherein the first holder is an upper chuck,
the second holder is a lower chuck, and
the first holder is connected to a suction device and vacuum-suctions the first substrate.

16. The bonding system according to claim 10, wherein the upper chuck includes:
a supporting member;
a main body supported by the supporting member, the main body including a plurality of pins brought into contact with a top surface of the first substrate, and
each of the supporting member and the main body include a through hole, the movable member being disposed in the through hole of the supporting member and the main body.

17. The bonding system according to claim 16, wherein the movable member includes:
a pressing pin;
a guide;
a motor; and
a position sensor.

18. The bonding system according to claim 17, wherein the motor moves the pressing pin along the vertical direction via the guide.

19. The bonding system according to claim 18, further comprising control circuitry configured to control a position and a speed of the motor to move the pressing pin from a standby position to a contact position and based on a detection result from the position sensor,
in the standby position, the pressing pin is higher than a top surface of the first substrate, and
in the contact position, the pressing pin is in contact with the first substrate.

20. The bonding system according to claim 19, wherein the control circuitry is further configured to:
control the motor to move the pressing pin to a bonding position, the bonding position being lower than the contact position and where a central portion of the first substrate comes into contact with the second substrate.
